(19) United States
(12) Patent Application Publication
(10) Pub. No.: US 2016/0013621 A1
(43) Pub. Date: Jan. 14, 2016

(54) DISTRIBUTED FEEDBACK LASER DIODE ARRAY AND METHOD OF MANUFACTURING SAME

(71) Applicant: Electronics and Telecommunications Research Institute, Daejeon (KR)

(72) Inventors: Young Ahn LEEM, Daejeon (KR); Kisoo KIM, Seoul (KR); Oh Kee KWON, Daejeon (KR); Young-Tak Han, Daejeon (KR)

(73) Assignee: Electronics and Telecommunications Research Institute, Daejeon (KR)

(21) Appl. No.: 14/608,385

(22) Filed: Jan. 29, 2015

(30) Foreign Application Priority Data
Jul. 9, 2014 (KR) 10-2014-0085977

(51) Int. Cl. H01S 5/40; H01S 5/12; H01S 5/028; H01S 5/343

(52) U.S. Cl. CPC H01S 5/4025; H01S 5/3434; H01S 5/4018; H01S 5/1231; H01S 5/028

(57) ABSTRACT

Provided is a method of manufacturing a distributed feedback laser diode array (DFB-LDA) including: forming active layers corresponding to a plurality of channels using electron beam lithography; forming a plurality of mask patterns between the active layers; and growing the active layers using electron beam lithography, wherein the opening widths of the plurality of mask patterns corresponding to the plurality of channels are different from one another.

### CROSS-REFERENCE TO RELATED APPLICATIONS

This U.S. non-provisional patent application claims priority under 35 U.S.C. §119 of Korean Patent Application No. 10-2014-0085977, filed on Jul. 9, 2014, the entire contents of which are hereby incorporated by reference.

### BACKGROUND OF THE INVENTION

The present invention disclosed herein relates to a distributed feedback laser diode array and a method of manufacturing the same.

A quick operation and miniaturization are consistently needed for an optical transceiver for data transmission. The quick operation is related to the performance of a chip-level unit element and a 10 Gb/s product currently is the main product of the market. However, a 100 Gb/s communication transceiver exceeding 10 Gb/s is configured by collecting 10 Gb/s discretes and performing optical fiber-based integration, under the current commercializing technology. When ten 10G discretes are collected to configure 100G transceiver, a transceiver having a size corresponding to an iPhone's size is configured due to a problem with a space occupied by optical fiber and a splitter.

In order to configure a transceiver having a smaller form factor, a monolithic integration or hybrid integration technology should be applied. The two technologies all need an array-type element.

In the case of the array-type element, an active-layer structure should be optimized on a channel by channel basis. In the case of an optical transceiver for data center, wavelength spacing should be 8 nm and each channel should allow 10 Gb/s direct modulation. Each channel should have an active layer that has a gain suitable for a lasing wavelength.

### SUMMARY OF THE INVENTION

The present invention provides a distributed feedback laser diode array implementing a quick operation and enabling miniaturized manufacturing and a method of manufacturing the same.

Embodiments of the present invention provide methods of manufacturing a distributed feedback laser diode array (DFB-LDA) including: forming active layers corresponding to a plurality of channels using electron beam lithography; forming a plurality of mask patterns between the active layers; and growing the active layers using electron beam lithography, wherein the opening widths of the plurality of mask patterns corresponding to the plurality of channels are different from one another.

In some embodiments, each of the plurality of channels may include an epitaxial layer, and the epitaxial layer may include a grating layer and at least one separate confinement hetero-structure (SCH) layer.

In other embodiments, the grating layer may include a duty grating formed by the electron beam lithography and dry etching.

In still other embodiments, mask patterns corresponding respectively to the plurality of channels may be formed in bilateral symmetry.

In even other embodiments, the widths of mask patterns corresponding to the plurality of channels may be different from one another.

In yet other embodiments, a geometrical parameter may be determined between the widths of the mask patterns corresponding to the plurality of channels and the opening widths corresponding to the plurality of channels.

In further embodiments, the number of the plurality of channels may be 10.

In still further embodiments, the methods may further include anti-reflection (AR) coating the sides of each of the plurality of channels.

In even further embodiments, the methods may further include growing a cladding layer after removing the plurality of mask patterns.

In yet further embodiments, the SAG technique may use an III-Group element for precursor diffusion.

In other embodiments of the present invention, distributed feedback laser diode arrays (DFB-LDA) may include: a first channel having a first active layer, wherein the first active layer is formed by first mask patterns by using an SAG technique; and a second channel having a second active layer, wherein the second active layer is formed by second mask patterns by using the SAG technique, Wherein the first mask patterns and the second mask patterns have different opening widths and the first and second channels are formed of different compositions.

In some embodiments, each of the first and second channels may be formed based on InGaAsP.

In other embodiments, each of the first and second channels may transmit data at a rate equal to or higher than 10 Gb/s.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 illustrates a selective area growth (SAG) mask for a distributed feedback laser diode array (DFB-LDA) according to an embodiment of the present invention;

FIG. 2 illustrates a cross-sectional view of a mask pattern used in an SAG process according to an embodiment of the present invention;

FIG. 3 shows room-temperature PL spectra for mask patterns having different values of an opening width Wo;

FIG. 4 shows a variation in wavelength for mask patterns having different values of an opening width Wo;

FIG. 5 shows optical fiber-coupled output spectra for a 10-channel DFB-LDA chip according to an embodiment of the present invention;

FIG. 6 shows fabry perot laser diode array (FP-LDA) spectra according to SAG according to an embodiment of the present invention; and

FIG. 7 is a flow chart of a method of manufacturing DFB-LDA according to an embodiment of the present invention.

### DETAILED DESCRIPTION OF PREFERRED EMBODIMENTS

In the following, the present invention is described clearly and in detail by using the accompanying drawings in such a manner that a person skilled in the art may easily practice the present invention.

A distributed feedback laser diode array (DFB-LDA) according to an embodiment of the present invention may use a selective area growth (SAG) technique to implement a plurality of channels. In this example, each of the plurality of channels may be formed based on InGaAsP. The SAG may form a silicon nitride (SiNx) and silica (SiO2) layer pattern on a substrate and promote the growth of a layer-free location to change the physical property of an active layer. Through the SAG technique, each of DFB-LDA channels may have an active layer having a gain suitable for a wavelength of each channel.

In the general case of the SAG, the growth of a selected region is promoted by the precursor diffusion of III-Group elements (e.g., B, Al, Ga, In, and Tl) when the selected region is open. Since the amount of the precursors of V-Group elements (e.g., N, P, As, Sb and Bi) is generally much more than that of III-Group elements, an influence by the precursors of V-Group elements is ignored. That is, by adjusting the amount of the precursors of III-Group elements according to the shape of an SAG mask pattern, the band gap of a specific region active layer may vary. The manufacturing of a single integrated optical element is easy.

Thus, in order to implement a 10-channel element, an energy band gap should vary, maintaining a modulation characteristic. Such a variation may adjusted by two phenomena. Firstly, the band gap of a self-material may vary by a variation in composition ratio of indium (In) to gallium (Ga). Secondly, the band gap may vary by a variation in bond energy generated from a quantum structure depending on a variation in stacked amount without a variation in composition. In order to increase the speed band width of direct modulation, a quantum well structure having compressive strain is suitable. However, since strain added when the SAG technique is used varies depending on an SAG mask structure, it is difficult to implement a multi-channel element. Thus, when the SAG technique is applied, a variation in composition of a material, namely, a variation in strain should be minimized.

In an embodiment, when ten channels having a wavelength spacing of 8 nm are implemented, the gain center should vary by 70 nm or more by using the SAG technique. In this case, an SAG mask should experience a big variation. The amount of strain added to each channel may not be constant. As a result, when the wavelength spacing of each channel is wide and there are many channels, it may be difficult to optimize all channels due to additional strain resulting from the principle of the SAG technique.

In the following, an SAG mask pattern for manufacturing a multi-channel element is described.

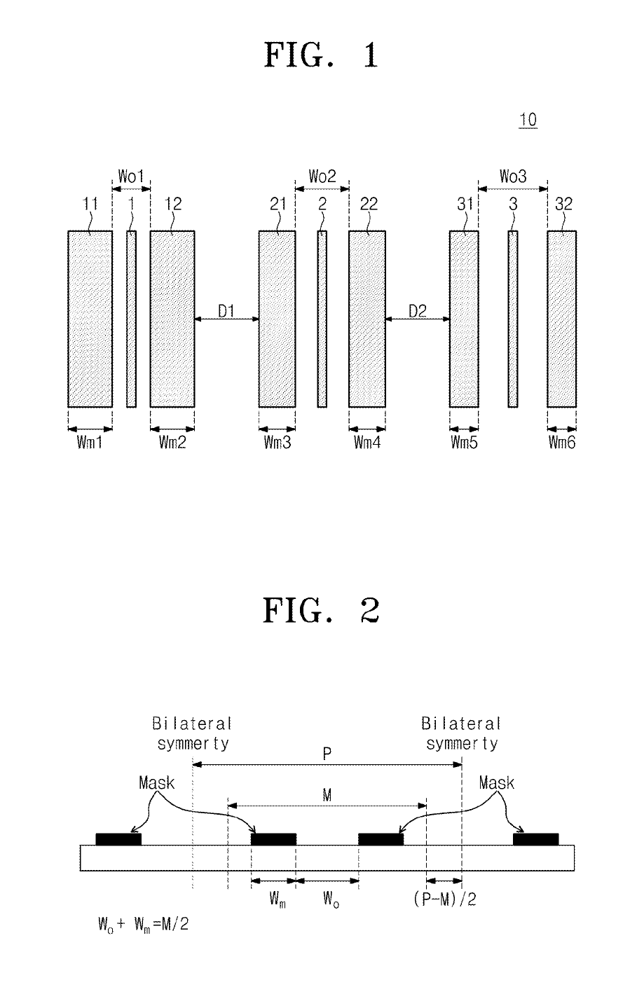

FIG. 1 shows an SAG mask pattern for the DFB-LDA according to an embodiment of the present invention. Referring to FIG. 1, a plurality of SAG mask patterns 11, 12, 21, 22, 31 and 32 are arranged between laser diode formation regions 1 to 3 corresponding to channels, respectively. In FIG. 1, mask patterns for three channels are shown for the convenience of description.

The SAG mask patterns 11, 12, 21, 22, 31 and 32 are located at both sides of the laser diode formation regions 1 to 3, respectively.

As shown in FIG. 1, a first SAG mask pattern 11 is located on the left side of a first laser diode formation region 1, and a second SAG mask pattern 12 is located on the right side of the first laser diode formation region 1. In this example, the first SAG mask pattern 11 and the second SAG mask pattern 12 are the SAG mask patterns of a first channel.

A third SAG mask pattern 21 is located on the left side of a second laser diode formation region 2, and a fourth SAG mask pattern 22 is located on the right side of the second laser diode formation region 2. In this example, the third SAG mask pattern 21 and the fourth SAG mask pattern 22 are the SAG mask patterns of a second channel.

Also, a fifth SAG mask pattern 31 is located on the left side of a third laser diode formation region 3, and a sixth SAG mask pattern 32 is located on the right side of the third laser diode formation region 3. In this example, the fifth SAG mask pattern 31 and the sixth SAG mask pattern 32 are the SAG mask patterns of a third channel.

Two important factors in configuring an active layer for 10 GHz direct modulation are an optical confinement factor and a carrier transport time. The optical confinement factor is related to the number of quantum wells. The direct modulation speed of a laser diode is maximized when there are about ten quantum wells or less. Also, the main variable of the carrier transport time may be determined by the width of a separate confinement hetero-structure (SCH). Thus, the carrier transport time may be enhanced as the width of the SCH is narrow. In this case, the width of the SCH does should not cause a damage to the performance of a laser diode.

In an embodiment, when the SAG is performed on ten channels, the widths of all layers may increase by growth rate enhancement. Accordingly, since the speed of direct modulation decreases and a growth thickness becomes thick, it may be difficult to increase the number of quantum wells due to a limitation in critical thickness determined by strain. Thus, an element having ten channels should minimize growth rate enhancement by the SAG and adjust the amount of strain to below critical strain with respect to growth thickness.

Also, since the element having ten channels may not form an SAG pattern having a repetitive shape, a variation in gain center equal to or greater than 70 nm should be obtained by a progressive variation in pattern. In order to obtain a variation in gain center of an active layer as much as possible, the width of a quantum well should be minimized and the variation direction of strain by the SAG should be tensile strain.

In an embodiment, the SAG mask pattern 10 may set the width of the quantum well to about 50 Å that is a limit not changing the property of a laser diode. In an embodiment, the width of the SCH may also be set to about 600 Å. Also, compressive strain has a value of about 0.68%.

The distances D1 and D2 between the channels of SAG masks may adjust the interference phenomenon of the SAG mask pattern 10. The distances D1 and D2 between SAG mask patterns 12 and 21, and 22 and 31 in different channels may have the same value.

For example, the width Wm1 of the first SAG mask pattern 11 and the width Wm2 of the second SAG mask pattern 12 are wider in comparison to those of other SAG mask patterns. In this case, the distance Wo1 between the first and second SAG mask patterns 11 and 12 is shorter in comparison to those between other SAG mask patterns.

Also, the widths Wm3 and Wm4 of the third and fourth SAG mask patterns 21 and 22 are narrower in comparison to those of the first and second mask patterns 11 and 12. Also, the distance Wo2 between the third and fourth SAG mask patterns 21 and 22 is longer in comparison to that between the first and second mask patterns 11 and 12 as the widths Wm3 and Wm4 decrease.

Also, the widths Wm5 and Wm6 of the fifth and sixth SAG mask patterns 31 and 32 are narrower in comparison to those of the third and fourth mask patterns 21 and 22. Also, the distance Wo3 between the fifth and sixth SAG mask patterns 31 and 32 is longer in comparison to that between the third and fourth mask patterns 21 and 22 as the widths Wm5 and Wm6 decrease.

SAG masks for three channels have been described above for the convenience of description. However, even in the case of SAG mask patterns for ten channels, the widths of SAG masks may progressively decrease for each channel in the same manner as in the SAG mask pattern for three channels. For example, the widths of mask patterns progressively decrease from a first channel to a tenth channel. That is, the widths of SAG mask patterns corresponding to a first channel are widest and the widths of SAG mask patterns corresponding to a tenth channel are narrowest. Also, the distance between SAG mask patterns of the tenth channel is longest and the distance of SAG mask patterns of the first channel is shortest.

The SAG mask pattern 10 according to an embodiment of the present invention maintains a certain distance between SAG mask patterns in order to decrease the interference between SAG mask patterns in each channel. Through a variation in distance between such SAG mask patterns, it is possible to easily configure an active layer through a fine adjustment in each of ten channels. Also, it is possible to secure the linear variation of SAG through a variation in distance even at the edges of the SAG mask patterns.

According to the mask pattern 10 of the present invention, the distance between SAG mask patterns in each channel has a length that may cause variations in concentration of indium (In) and gallium (Ga) by the difference in diffusion length between indium (In) and gallium (Ga). In and embodiment, the length may be about 50 μm to 100 μm but vary depending on growth equipment or conditions. Thus, SAG mask patterns for first to tenth channels may manufacture a multi-channel element that supports a wavelength of about 1525 nm to about 1597 nm, i.e., about 70 nm.

In an embodiment, the width between masks may be set to a size that may cause a variation in concentration of indium (In) and gallium (Ga) by the difference in diffusion length between indium (In) and gallium (Ga). In an embodiment, the diffusion length may be about 50 nm to 100 nm. It varies depending on growth equipment and conditions. In order to test such a technique, when a mask is formed to decrease the width of a mask pattern from 100 nm and only an active layer including the SCH grows by using SAG, the following result is obtained. When the width of an SAG mask widens, a central wavelength varies. In this case, a total variation in gain center is about 100 nm. It is difficult to describe such a variation in gain center by using a variation in width of a quantum well and it may be understood as a variation in composition of InGaAsP in SAG. An increase in content of indium (In) changes a band gap to a long wavelength and applies compressive strain to the quantum well (QW).

When a thin QW structure is used for the shape of a mask proposed by the present invention, an active layer may grow within a critical thickness.

A method of manufacturing a distributed feedback laser diode array (DFB-LDA) according to an embodiment of the present invention may constrain a growth rate enhancement factor to 1.35 and also secure the movement of gain center of 100 nm. In an embodiment, an SAG mask pattern shape that may fine-adjust an SAG effect may be used. In an embodiment, an SAG mask pattern shape that may finely adjust an SAG effect may be used.

The 10-channel DFB-LDA according to an embodiment of the present invention may transmit a 100 Gb/s signal separated by a 8 nm wavelength grid from the central wavelength of 1.55 μm. Since the DFB-LDA according to an embodiment of the present invention may use an SAG technique, an electron-beam lithography technique and a reverse-mesa ridge waveguide LD processing technique to manufacture each channel, it is possible to decrease an electrical or thermal resistance and provide accurate laser wavelength control and an excellent single mode yield.

The epitaxial layer of the DFB-LDA of the present invention may grow by lateral-flow metal-organic chemical vapor deposition (MOCVD). In this case, trimethylindium (TMIN), trimethylgallium (TMGa), phosphine (PH3), and arsine (AsH3) may be used as raw materials.

Before an SAG process, the epitaxial layer may include an n-InP buffer, a grating layer having a band gap wavelength of 1.3 μm, an n-InP space layer, and an external lattice-matched SCH layer of 1.08 μm. In this example, by changing a grating period according to a Bragg condition, the grating pattern may be designed to have a channel space of 8 nm for all channels. The Bragg condition is λ_{B}=2Λn_{eq}, for example. In this example, λ_{B} is a Bragg wavelength, Λ is a grating period, and n_{eq} is an equivalent refractive index.

In an embodiment, a quadrilateral duty grating may be formed by electronic-beam writing and dry-etching.

In an embodiment, mask patterns used for an SAG process may be of bilaterally symmetric shapes having a unit cell period P of 500 μm.

FIG. 2 illustrates a cross-sectional view of a mask pattern used in an SAG process according to an embodiment of the present invention. Referring to FIG. 2, the space between adjacent mask strips having the width Wm of a mask pattern in a unit cell is uniform as an opening width Wo. For such a mask pattern, a geometrical parameter M generating the relationship between the widths Wm and Wo is set. For example, Wm+Wo=M/2. SAG mask patterns having different opening widths Wo may be designed to obtain a gain spectrum near each channel wavelength.

In an embodiment, after mask patterning, SAG layers may grow under a certain temperature and a certain pressure. In this example, the SAG layers may be formed as InGaAsP. In this example, the certain temperature may be about 630° C. and the certain pressure may be about 100 mbar. In an embodiment, each of SAG layers may include an external SCH layer of about 10 nm, an internal SCH layer of about 20 nm, seven-pair QWs, an internal SCH layer of about 20 nm, and an external SCH layer of about 10 nm. In this example, the seven-pair QWs may include wells having a width of 6 nm having 0.6% compressive strain of 1.62 μm and barriers having a width of 7.4 nm having 0.45% tensile strain of 1.3 μm. After the SAG process, room-temperature PL measuring may be performed at the center of an open region.

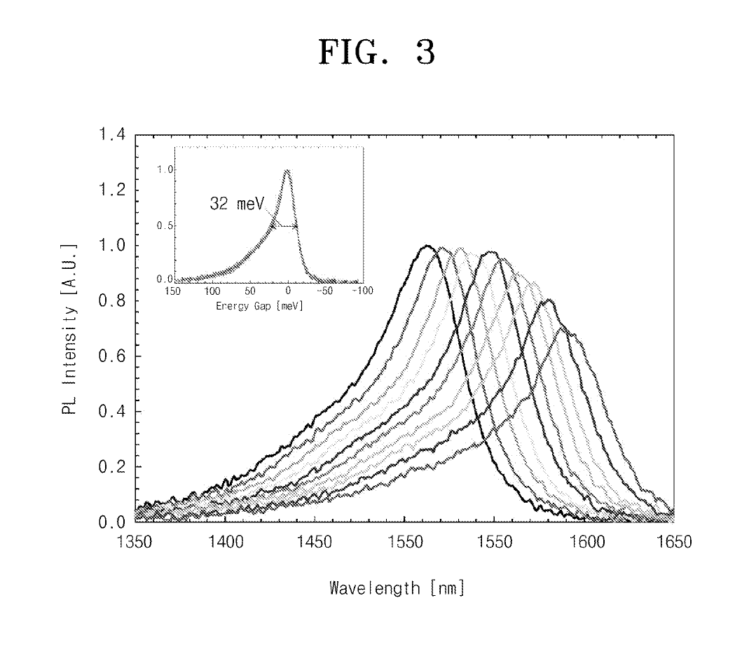

FIG. 3 shows room-temperature PL spectra for mask patterns having different values of an opening width, Wo. Referring to FIG. 3, the PL spectra is of about 32 mV full width at half maximum (FWHM) and have substantially the same shapes.

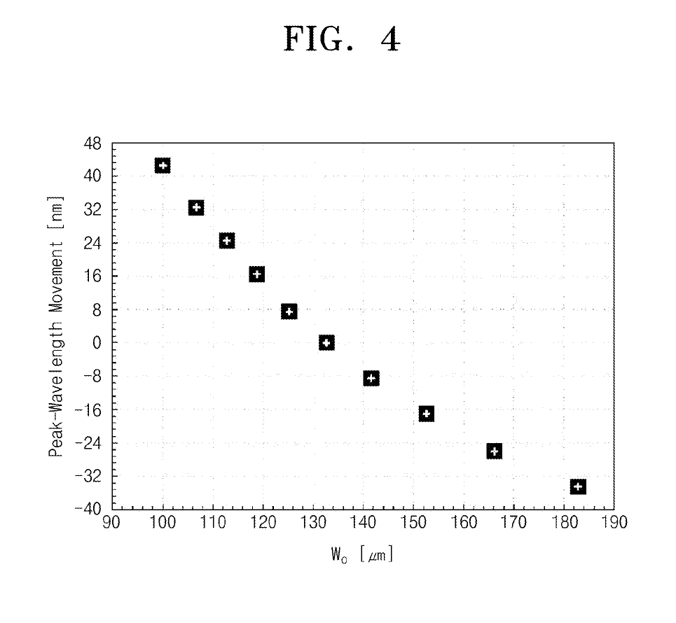

FIG. 4 shows a variation in peak wavelength for mask patterns having different values of an opening width Wo; Referring to FIG. 4, a peak intensity is apt to decrease to about 0.7 with a decrease in opening width Wo, unlike the test result of SAG layers formed on mask patterns having the same opening width Wo. In addition, a peak wavelength moves to the side of a long wavelength having a wavelength interval of approximately 8 nm. Such a movement results from a decrease in quantum level and from a decrease in band gap energy.

For example, at an opening width Wo of 100 μm, the widths of a quantum well and a bather are approximately 10 mm and 124 nm at indium (In)/gallium (Ga) growth speeds of 1.74/1.46, respectively.

After removing an SAG mask, an external SCH layer having a width of 30 nm, a p-InP residual cladding layer having a width of 100 nm, a p-InGaAsP etching stop layer having a width of 20 nm, a p-InP upper cladding layer having a width of 2 μm, and a p+InGaAs layer having a width of 0.2 μm sequentially grow. RM-RWGs having a ridge-neck width of approximately 2 μm may be manufactured.

After general LD manufacturing processes (e.g., benzo-cyclobutene (BCB), contact-layer opening, p-metallization, lapping, n-metallization, and scribing processes), two sides of a long DFB-LDA having a length of 300 μm are anti-reflection (AR) coated. In this example, an AR coating layer may be formed by the ion beam deposition of TiO₂ and SiO₂. A reflective index of Approximately 0.53% may be obtained from 1.55 μm.

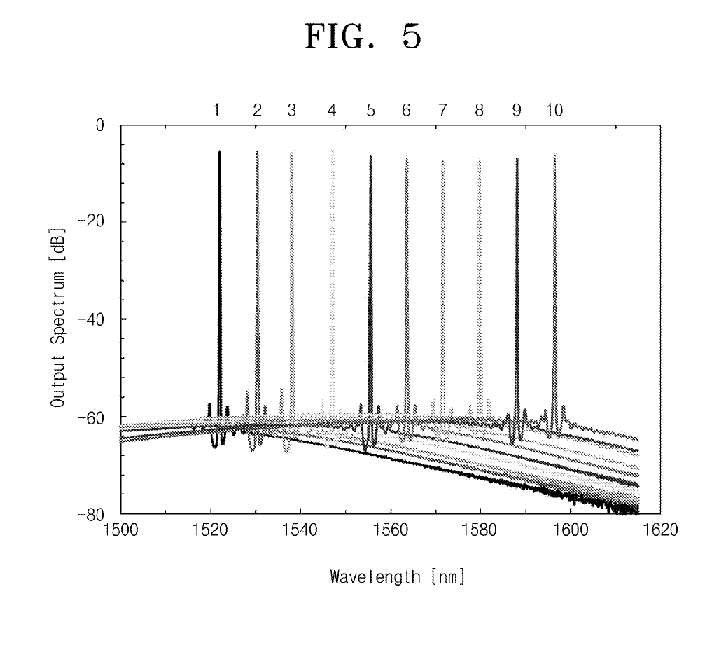

FIG. 5 shows general optical fiber-coupled output spectra for a 10-channel DFB-LDA chip. Referring to FIG. 5, all spectra is measured at a current of 50 mA. They show side-mode suppression ratios (SMSRs) equal to or higher than 50 dB having an average channel space of 8.2 nm.

The DFB-LDA according to an embodiment of the present invention may be manufactured as ten channels by SAG technique electron beam lithography. Measured PL spectra of SAG layers growing on a designed mask pattern shows substantially the same shape at a wavelength spacing of approximately 8 nm.

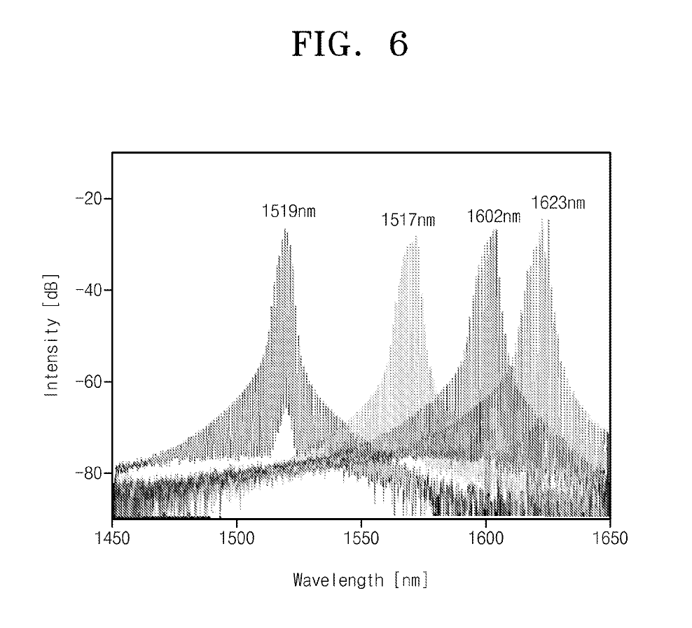

FIG. 6 shows fabry perot laser diode array (FP-LDA) spectra according to SAG according to an embodiment of the present invention. Referring to FIG. 6, in the case of the FP-LDA, matched spectra having a spectrum width of approximately 35 nm is represented at all channels without a significant variation in critical current or slope efficiency. It may be checked that good SAG has been performed through wavelengths 1519 nm, 1571 nm, 1602 nm, and 1623 nm. Since a variation in gain center width of about 70 nm is actually needed, a difference in thickness of an active layer on both ends does not exceed 1.28. It ensures uniformity in performance of the entire laser diode. Accordingly, it may be used for manufacturing a multi-channel element manufactured by using the SAG mask pattern proposed in the present invention, e.g., a DFB-LDA supporting ten channels.

The present invention may provide an SAG mask pattern for overcoming a technical limitation that it is difficult to optimize all channels due to additional strain resulting from the principle of an SAG method when the wavelength spacing of each channel is wide and there are many channels. To this end, the present invention may solve a limitation in ten channels having the above-described 8 nm wavelength spacing, by using the designs of an SAG mask and a growth structure.

The SAG mask pattern of the present invention may be used for manufacturing a multi-channel element of an optical transceiver for data center of which the wavelength spacing is 8 nm and which has an active-layer structure capable of performing 10 GHz direct modulation at each channel. To this end, the SAG mask pattern may maximize a variation in band gap, minimizing the structural variation of ten channels. Also, the SAG mask pattern may minimize a variation in strain.

In the case of the DFB-LDA, when SMSRs equal to or higher than 50 dB are obtained from almost all channels, an increase in critical current, expansion in channel space, a decrease in bandwidth, and enhancement in overshoot are represented. These variations are closely related to a decrease in coupling coefficient and an increase in reflection index in a manufactured waveguide structure including an SAG layer. Due to a wide modulation bandwidth equal to or higher than 10 GHz for all channels, a module clearly shows an eye opening before and after a 2 km transport. As a result, the DFD-LDA of the present invention may operate a data rate of 10 Gb/s and may be used as a low-cost light source for a 100 Gb/s Ethernet transceiver.

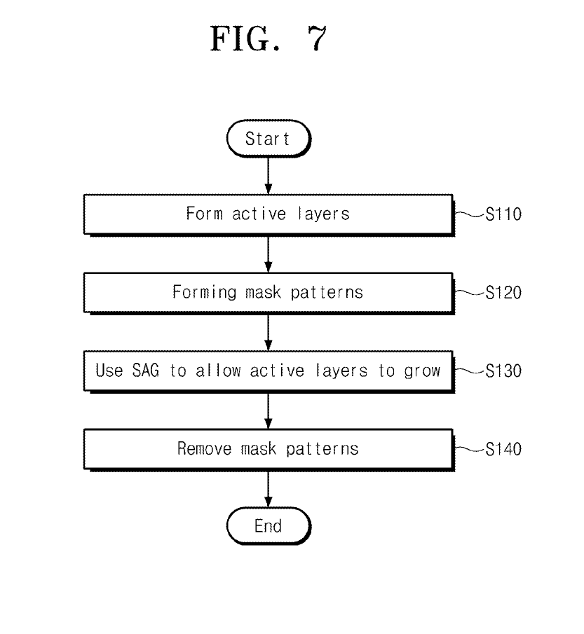

FIG. 7 is a flow chart of a method of manufacturing a DFB-LDA according to an embodiment of the present invention. Referring to FIGS. 1 to 7, the method of manufacturing the DFB-LDA is as follows.

Active layers corresponding to a plurality of channels are formed by using electron beam writing and etching processes in step S110. Mask patterns of each of a plurality of channels are formed in step S120. In this case, the width Wm of mask patterns Wm and an opening width Wo may be different for each channel. See FIGS. 1 and 2 for details. Then, the active layers grow by using SAG in step S130. Then, mask patterns are removed in step S140.

The method of manufacturing the DFB-LDA according to an embodiment of the present invention may be manufactured simply and at low costs by using the SAG.

Since the DFB-LDA according to an embodiment of the present invention implements a plurality of channels having different wavelengths by using the SAG technique as described above, costs may be reduced and miniaturization may be achieved.

The content of the present invention as described above is only particular embodiments for carrying out the present invention. The present invention may include a particular, actually available means and a technical spirit that is an abstract, conceptual idea capable of being utilized as a technology in the future.

What is claimed is:

1. A method of manufacturing a distributed feedback laser diode array (DFB-LDA), the method comprising:
forming active layers corresponding to a plurality of channels using electron beam lithography;
forming a plurality of mask patterns between the active layers; and
growing the active layers using electron beam lithography,
wherein the opening widths of the plurality of mask patterns corresponding to the plurality of channels are different from one another.

2. The method of claim 1, wherein each of the plurality of channels comprises an epitaxial layer,
wherein the epitaxial layer comprises a grating layer and at least one separate confinement hetero-structure (SCH) layer.

3. The method of claim 2, wherein the grating layer comprises a duty grating formed by the electron beam lithography and dry etching.

4. The method of claim 1, wherein mask patterns corresponding respectively to the plurality of channels are formed in bilateral symmetry.

5. The method of claim 1, wherein the widths of mask patterns corresponding to the plurality of channels are different from one another.

6. The method of claim 1, wherein a geometrical parameter is determined between the widths of the mask patterns corresponding to the plurality of channels and the opening widths corresponding to the plurality of channels.

7. The method of claim 1, wherein the number of the plurality of channels is 10.

8. The method of claim 1, further comprising anti-reflection (AR) coating the sides of each of the plurality of channels.

9. The method of claim 1, further comprising growing a cladding layer after removing the plurality of mask patterns.

10. The method of claim 1, wherein the SAG technique uses an III-Group element for precursor diffusion.

11. A distributed feedback laser diode array (DFB-LDA), the DFB-LDA comprising:
a first channel having a first active layer, wherein the first active layer is formed by first mask patterns by using an SAG technique; and
a second channel having a second active layer, wherein the second active layer is formed by second mask patterns by using the SAG technique,
wherein the first mask patterns and the second mask patterns have different opening widths, and
wherein the first and second channels are formed of different compositions.

12. The DFB-LDA of claim 11, wherein each of the first and second channels is formed based on InGaAsP.

13. The DFB-LDA of claim 11, wherein each of the first and second channels transmits data at a rate equal to or higher than 10 Gb/s.
